(19) United States
(12) Patent Application Publication
(10) Pub. No.: US 2023/0076784 A1
(43) Pub. Date: Mar. 9, 2023

(54) HEAT DISSIPATION ASSEMBLY AND ELECTRONIC ASSEMBLY

(71) Applicants: Inventec (Pudong) Technology Corporation, Shanghai (CN); INVENTEC CORPORATION, Taipei (TW)

(72) Inventors: Kai-Yang TUNG, Taipei (TW); Hung-Ju CHEN, Taipei (TW)

(21) Appl. No.: 17/839,752

(22) Filed: Jun. 14, 2022

(30) Foreign Application Priority Data
Sep. 6, 2021 (CN) 202111039358.1
Sep. 6, 2021 (CN) 202111039371.7

(51) Int. Cl. H05K 7/20

(52) U.S. Cl. CPC H05K 7/20318; H05K 7/20145; H05K 7/20154; H05K 7/20172; H05K 7/20327; H05K 7/20409

(57) ABSTRACT

A heat dissipation assembly and an electronic assembly, wherein the heat dissipation assembly includes condensers and fan, the condensers each include first chamber body, second chamber body, and pipes. Two opposite ends of each pipe are respectively in fluid communication with the first and second chamber bodies, every two of the pipes located adjacent to each other define a heat dissipation gap therebetween. The first and second chamber bodies and the pipes together define a heat dissipation channel which is in air communication with the heat dissipation gaps. The fan is disposed on the condensers and in air communication with the heat dissipation channel and configured to guide an airflow flowing through the heat dissipation channel and the heat dissipation gaps so as to cool the working fluid flowing through the pipes.

### CROSS-REFERENCE TO RELATED APPLICATIONS

This non-provisional application claims priority under 35 U.S.C. § 119(a) on Patent Application No(s). 202111039371.7 filed in China, on Sep. 6, 2021 and on Patent Application No(s). 202111039358.1 filed in China, on Sep. 6, 2021, the entire contents of which are hereby incorporated by reference.

### BACKGROUND OF THE INVENTION

### Technical Field of the Invention

The invention relates to a heat dissipation assembly and an electronic assembly, more particularly to a heat dissipation assembly including a plurality of condensers that have heat dissipation channels and an electronic assembly including the heat dissipation assembly.

### Description of the Related Art

Immersion cooling can cool heat source in a system by immersing the heat source into a bath of thermally conductive dielectric liquid or dripping thermally conductive dielectric liquid onto the heat source. The thermally conductive dielectric liquid is boiled by the heat source and turned into vapor, and the vapor is then condensed by a single piece of condenser disposed in a housing of the system.

However, the typical single piece of condenser is unable to meet the growing heat dissipation demand for advanced heat source. Increase the volume of the conventional condenser might help improve its heat dissipation but is unfavorable for the space utilization of the system. This problem makes it difficult in achieving a balance between improving the performance of condenser and optimizing space utilization of system.

Also, the hot airflow emitted from the conventional condenser is discharged out from a side of the system housing that contains holes for maintenance and thereby affecting the maintenance personnel from doing their works.

### SUMMARY OF THE INVENTION

The invention provides a heat dissipation assembly and an electronic assembly capable of improving heat dissipation of condenser while being applied to a limited internal space and preventing hot airflow from emitting out of electronic device to affect the maintenance works.

One embodiment of this invention provides a heat dissipation assembly configured for a working fluid to flow therethrough and including a plurality of condensers and a fan, the plurality of condensers each include a first chamber body, a second chamber body, and a plurality of pipes. In each of the plurality of condensers, two opposite ends of each of the plurality of pipes are respectively in fluid communication with the first chamber body and the second chamber body, every two of the plurality of pipes located adjacent to each other define a heat dissipation gap therebetween, the working fluid is configured to flow from the first chamber body to the second chamber body via the plurality of pipes. The first chamber bodies, the second chamber bodies, and the plurality of pipes of the plurality of condensers together define a heat dissipation channel therebetween, the heat dissipation channel is in air communication with the heat dissipation gaps between the plurality of pipes. The fan is disposed on the plurality of condensers and in air communication with the heat dissipation channel and configured to guide an airflow flowing through the heat dissipation channel and the heat dissipation gaps between the plurality of pipes of the plurality of condensers so as to cool the working fluid flowing through the plurality of pipes.

Another embodiment of this invention provides an electronic assembly configured for a working fluid to flow therethrough and including a rack, a housing, an electronic device, a heat dissipation assembly, and a filter. The housing is disposed on the rack. The electronic device is disposed in the housing. The heat dissipation assembly includes a plurality of condensers and a fan, the plurality of condensers each include a first chamber body, a second chamber body, and a plurality of pipes. In each of the plurality of condensers, two opposite ends of each of the plurality of pipes are respectively in fluid communication with the first chamber body and the second chamber body, every two of the plurality of pipes located adjacent to each other define a heat dissipation gap therebetween, the working fluid is configured to flow from the first chamber body to the second chamber body via the plurality of pipes. The first chamber bodies, the second chamber bodies, and the plurality of pipes of the plurality of condensers together define a heat dissipation channel therebetween, the heat dissipation channel is in air communication with the heat dissipation gaps between the plurality of pipes. The fan is disposed on the plurality of condensers and in air communication with the heat dissipation channel and configured to guide an airflow flowing through the heat dissipation channel and the heat dissipation gaps between the plurality of pipes of the plurality of condensers so as to cool the working fluid flowing through the plurality of pipes. The heat dissipation assembly is disposed on the rack and located at a side of the housing, the plurality of condensers of the heat dissipation assembly are in fluid communication with the electronic device. The filter is disposed on a side of the heat dissipation assembly located away from the housing so that the airflow guided by the fan of the heat dissipation assembly passes through the filter before reaching the heat dissipation channel.

Another embodiment of this invention provides condenser including two chamber bodies, a first row pipe and a second row pipe. The two chamber bodies each include an installation surface. The first row pipe includes a plurality of first pipes, the second row pipe includes a plurality of second pipes, two opposite ends of each of the plurality of first pipes are respectively disposed through the installation surfaces of the two chamber bodies and are respectively in fluid communication with the two chamber bodies, two opposite ends of each of the plurality of second pipes are respectively disposed through the installation surfaces of the two chamber bodies and are respectively in fluid communication with the two chamber bodies, every two of the plurality of first pipes located adjacent to each other define a first heat dissipation gap therebetween, every two of the plurality of second pipes located adjacent to each other define a second heat dissipation gap therebetween, the first heat dissipation gaps are in air communication with at least one of the second heat dissipation gaps.

According to the embodiments of this invention discussed above, the first chamber bodies, second chamber bodies, and pipes of the condensers together define a heat dissipation channel and heat dissipation gaps which are located between the pipes and in air communication with the heat dissipation channel, thus airflow generated by fan is allowed to flow through the heat dissipation channel and the heat dissipation gaps and therefore effectively cools working fluid passing through the pipes. As such, the condenser is able to achieve a sufficient heat dissipation while being applied to a limited internal space.

In addition, the fan is able to guide airflow from the heat dissipation gaps between the pipes to the heat dissipation channel, such that the airflow flows away from the electronic device and will not affect the maintenance works of the electronic device.

Further, the fan is able to guide airflow from the heat dissipation channel to the heat dissipation gaps between the pipes, and the filter is arranged at a side of the heat dissipation assembly located away from the housing, thus airflow from the fans passes through the filter before reaching the heat dissipation channel and therefore the filter can prevent dust from accumulating on the fans or the condenser, thereby preventing the performance of the fans and the condenser from being affected by dust.

### BRIEF DESCRIPTION OF THE DRAWINGS

The present invention will become more fully understood from the detailed description given hereinbelow and the accompanying drawings which are given by way of illustration only and thus are not limitative of the present invention and wherein:

FIG. 1 is a perspective view of a heat dissipation assembly of the invention;

FIG. 2 is an exploded view of the heat dissipation assembly in FIG. 1;

FIG. 3 is an exploded view of a condenser of according to a first embodiment of the heat dissipation assembly in FIG. 1;

FIG. 4 is a partially enlarged cross-sectional view of the condenser of the first embodiment of the heat dissipation assembly in FIG. 1;

FIG. 5 is an exploded view of a condenser according to a second embodiment of the heat dissipation assembly of the invention;

FIG. 6 is a partially enlarged cross-sectional view of the condenser of the second embodiment of the heat dissipation assembly in FIG. 5; and

FIG. 7 is a side view of an electronic assembly according to one embodiment of the invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

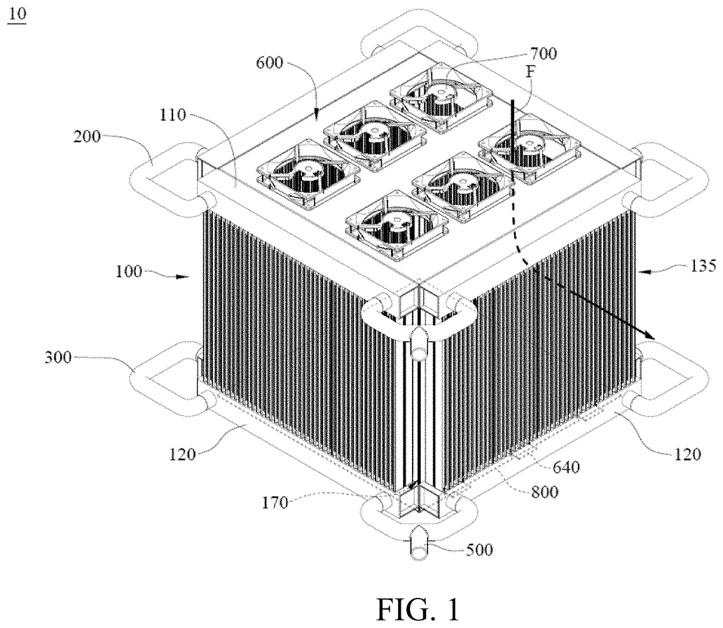

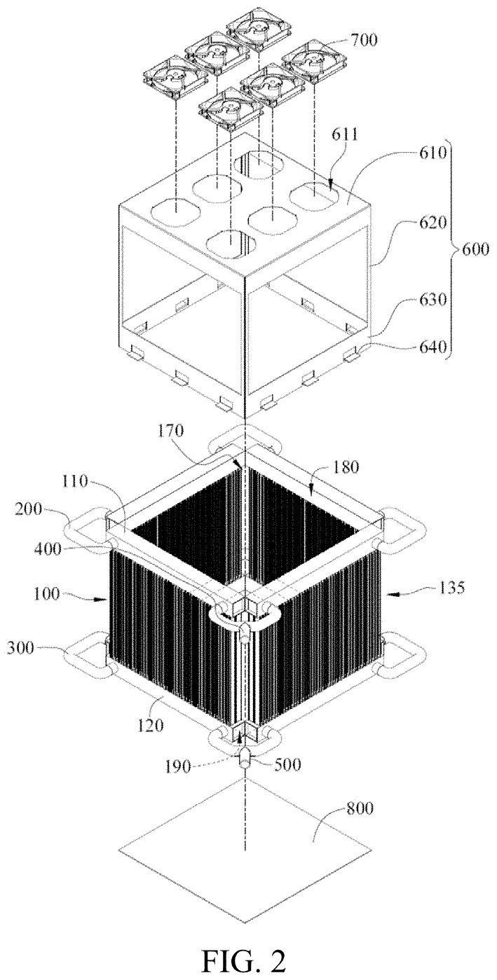

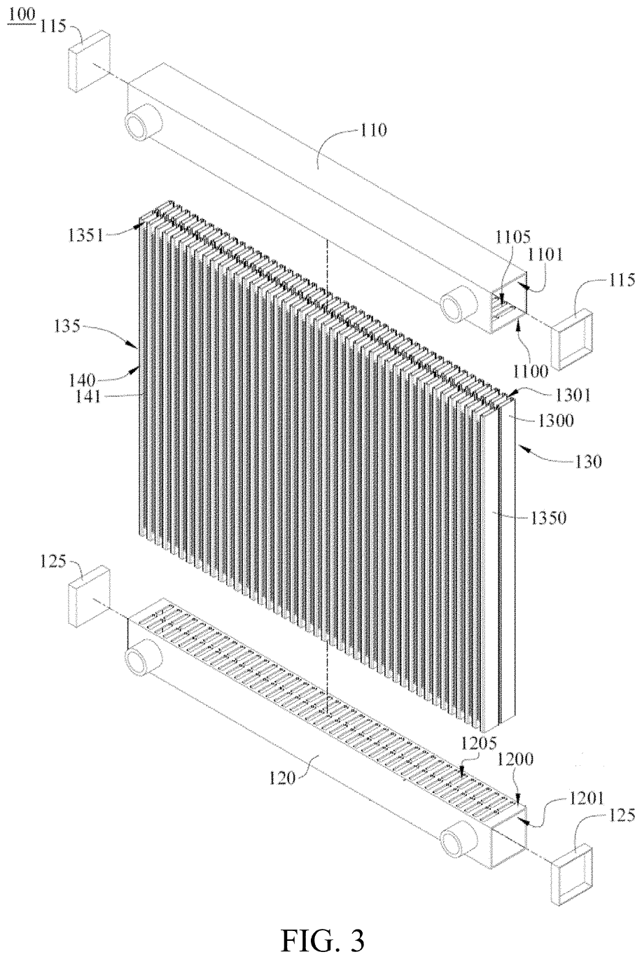

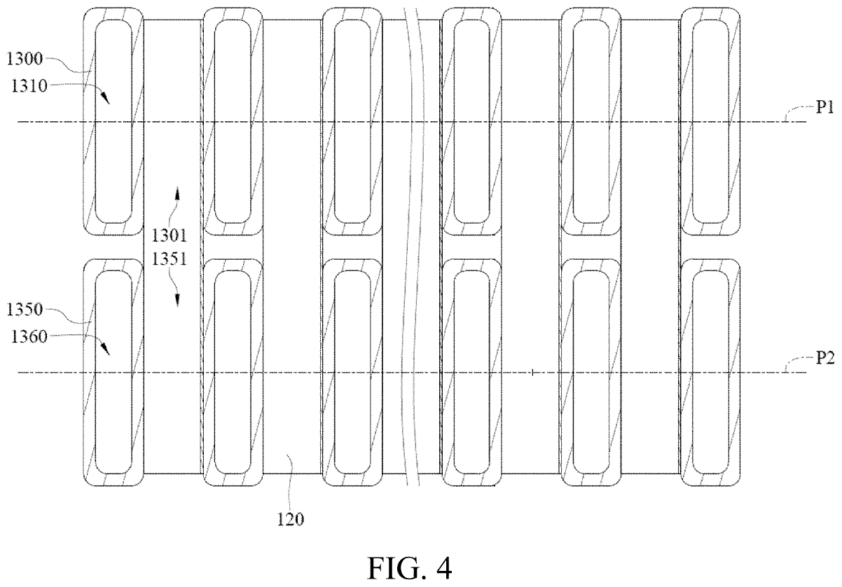

Please refer to FIGS. 1-4. FIG. 1 is a perspective view of a heat dissipation assembly of the invention. FIG. 2 is an exploded view of the heat dissipation assembly in FIG. 1. FIG. 3 is an exploded view of a condenser of according to a first embodiment of the heat dissipation assembly in FIG. 1. FIG. 4 is a partially enlarged cross-sectional view of the condenser of the first embodiment of the heat dissipation assembly in FIG. 1.

In this embodiment, a heat dissipation assembly 10 is provided and configured for a working fluid (not shown) to flow therethrough and to flow through, for example, an immersion cooling (not shown). The working fluid may be a dielectric liquid. It is known that an immersion cooling is a type of liquid cooling that is capable of immersing heat source (not shown) into a bath of non-conductive working fluid or capable of dripping non-conductive working fluid onto the heat source (not shown).

In this embodiment, the heat dissipation assembly 10 includes a plurality of condensers 100, a plurality of first connecting pipes 200, a plurality of second connecting pipes 300, an inflow pipe 400, an outflow pipe 500, a fan rack 600, a plurality of fans 700, and a baffle 800.

In this embodiment, the condensers 100 each include a first chamber body 110, two first lid plates 115, a second chamber body 120, two second lid plates 125, a first row pipe 130, a second row pipe 135 and a heat sink 140.

The first chamber bodies 110, the second chamber bodies 120, the first row pipes 130, and the second row pipes 135 of the condensers 100 together define a heat dissipation channel 170 therebetween. The first chamber bodies 110 of the condensers 100 together define a first opening 180 therebetween. The second chamber bodies 120 of the condensers 100 together define a second opening 190 therebetween. The first opening 180 and the second opening 190 are in air communication with two opposite ends of the heat dissipation channel 170. The first chamber bodies 110 of the condensers 100 are in fluid communication with one another via the first connecting pipes 200. The second chamber bodies 120 of the condensers 100 are in fluid communication with one another via the second connecting pipes 300. The inflow pipe 400 is in fluid communication with one of the first connecting pipes 200 and is configured to receive a working fluid in gas state. The outflow pipe 500 is in fluid communication with one of the second connecting pipes 300 and is configured to discharge a working fluid in liquid state.

In other embodiments, the heat dissipation assembly may omit the first connecting pipes 200 and the second connecting pipes 300; in such a case, the first chamber bodies of the condensers may be not in fluid communication with one another, the second chamber bodies of the condensers may be not in fluid communication with one another, either, and these condensers may each have an outflow pipe and an inflow pipe.

Since the condensers 100 are similar in configuration, the following paragraphs will only describe only one of them in detail for the purpose of simplicity. Please refer to FIGS. 3 and 4. FIG. 3 is an exploded view of a condenser of according to a first embodiment of the heat dissipation assembly in FIG. 1. FIG. 4 is a partially enlarged cross-sectional view of the condenser of the first embodiment of the heat dissipation assembly in FIG. 1. The first chamber body 110 includes a first installation surface 1100 and a first through chamber 1101. The two first lid plates 115 are respectively fixed at two opposite sides of the first chamber body 110 so as to cover the first through chamber 1101 and thereby preventing working fluid from leaking from the first through chamber 1101. The first installation surface 1100 faces away from the first through chamber 1101 and includes a plurality of first installation holes 1105. The first installation holes 1105 are in fluid communication with the first through chamber 1101. The second chamber body 120 includes a second installation surface 1200 and a second through chamber 1201. The two second lid plates 125 are respectively fixed at two opposite sides of the second chamber body 120 so as to cover the second through chamber 1201 and thereby preventing working fluid from leaking from the second through chamber 1201. The second installation surface 1200 faces away from the second through chamber 1201 and includes a plurality of second installation holes 1205. The second installation holes 1205 are in fluid communication with the second through chamber 1201. In addition, the first installation surface 1100 and the second installation surface 1200 face toward each other.

The first row pipe 130 includes a plurality of first pipes 1300. The second row pipe 135 includes a plurality of second pipes 1350. In the condenser of the first embodiment, the first pipe 1300 and the second pipe 1350 each are in a relatively flat shape. In this embodiment, the first pipes 1300 each include one first channel 1310, and the second pipes 1350 each include one second channel 1360. Two opposite ends of each first pipe 1300 are respectively inserted into at least part of the first installation holes 1105 on the first installation surface 1100 of the first chamber body 110 and at least part of the second installation holes 1205 on the second installation surface 1200 of the second chamber body 120, such that the first channels 1310 are in fluid communication with the first through chamber 1101 an the second through chamber 1201. Two opposite ends of each second pipe 1350 are respectively inserted into other part of the first installation holes 1105 on the first installation surface 1100 of the first chamber body 110 and other part of the second installation holes 1205 on the second installation surface 1200 of the second chamber body 120, such that the second channels 1360 are in fluid communication with the first through chamber 1101 an the second through chamber 1201. Every two adjacent first pipes 1300 define a first heat dissipation gap 1301 therebeween. Every two adjacent second pipes 1350 define a second heat dissipation gap 1351 therebeween. In this embodiment, the first heat dissipation gaps 1301 are respectively in air communication with the second heat dissipation gaps 1351. In addition, as shown in FIG. 4, in this embodiment, the first pipes 1300 are parallel with one another on a first reference plane P1, the second pipes 1350 are parallel with one another on a second reference plane P2, and the first reference plane P1 is parallel with the second reference plane P2. The working fluid flows from the first through chamber 1101 of the first chamber body 110 to the second through chamber 1201 of the second chamber body 120 via the first pipes 1300 and the second pipes 1350.

As shown in FIGS. 3 and 4, in this embodiment, the heat sink 140 includes a plurality of heat sink fins 141. The heat sink fins 141 are respectively disposed in the first heat dissipation gaps 1301 between the first pipes 1300 and in the second heat dissipation gaps 1351 between the second pipes 1350.

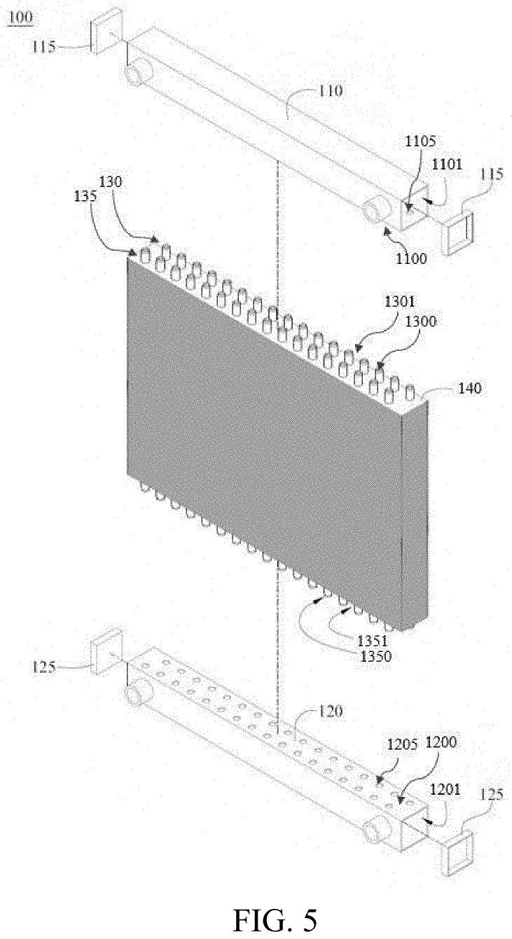

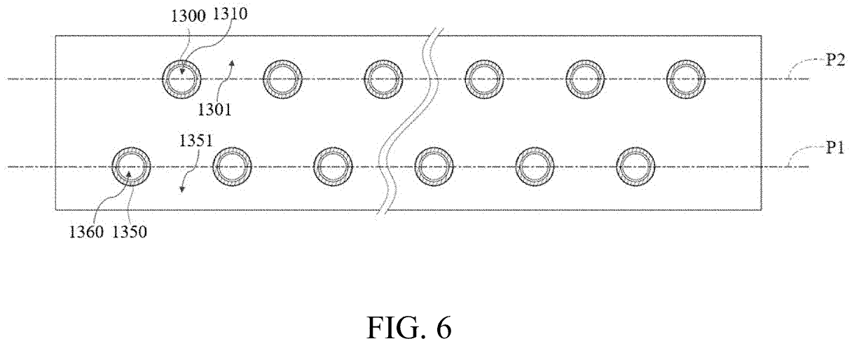

Please further refer to FIGS. 5 and 6, a condenser according to a second embodiment of the invention is provided. FIG. 5 is an exploded view of a condenser according to a second embodiment of the heat dissipation assembly of the invention. FIG. 6 is a partially enlarged cross-sectional view of the condenser of the second embodiment of the heat dissipation assembly in FIG. 5.

The main differences between this embodiment and previous embodiment are the shape and arrangement of pipes and the connection between the pipes and the heat sink. In detail, the first pipes 1300 and the second pipes 1350 are circular pipes disposed through the heat sink 140, and the first pipes 1300 are displaced from the second pipes 1350.

Note that the shape and arrangement of the pipes in the invention are not limiting. And the pipes of the invention are not limited to have only one channel. In the condenser of the first embodiment of the invention, the flat shape of the first pipes and the second pipes allows the first pipes and the second pipes to be arranged in a dense manner, such that the first pipes and the second pipes have sufficient contact surfaces with airflow for effectively cooling the working fluid in the first pipes and the second pipes. In the condenser of the second embodiment of the invention, the displaced first and second pipes enables more pipes in the condenser so that the flow rate of the working fluid passing through the condenser is increased and thereby improving the heat exchange efficiency of the working fluid relative to fan-driven airflow.

Please refer to FIGS. 1 and 2, in this embodiment, the fan rack 600 includes a first plate part 610, a plurality of support posts 620, a second plate part 630, and a plurality of protrusions 640. The first plate part 610 is disposed at the first opening 180 and includes a plurality of mount holes 611. The mount holes 611 are in air communication with the heat dissipation channel 170. Two opposite ends of each support post 620 are respectively fixed to the first plate part 610 and the second plate part 630. The protrusion 640 protrudes from the second plate part 630.

The fans 700 are respectively disposed at the mount holes 611 and are in air communication with the heat dissipation channel 170, thus the fans 700 are able to generate airflow F flowing through the first heat dissipation gaps 1301 between the first pipes 1300 and the second heat dissipation gaps 1351 between the second pipes 1350 from the heat dissipation channel 170, thereby cooling the working fluid flowing in the first row pipe 130. In other embodiments, the first plate part of the fan rack may be disposed in the heat dissipation channel and spaced apart from the first opening, such that the fans may be located in the heat dissipation channel and spaced apart from the first opening. The airflow F flows through the first heat dissipation gaps 1301 between the first pipes 1300 and the second heat dissipation gaps 1351 between the second pipes 1350 from the heat dissipation channel 170, thus a filter 24 may be arranged at an upstream of the airflow. As such, airflow F from the fans passes through the filter 24 before reaching the heat dissipation channel 170 and therefore the filter 24 can prevent dust from accumulating on the fans 700 or the condenser 100, thereby preventing the performance of the fans 700 and the condenser 100 from being affected by dust. In other embodiments, the fans may be used to guide airflow flowing in a direction opposite to the airflow F; that is, in other embodiments, the fans may be used to guide an airflow from the heat dissipation gaps between the pipes to the heat dissipation channel, such that the airflow flows away from the electronic device and will not affect the maintenance works of the electronic device.

In this embodiment, the baffle 800 is located between and clamped by the protrusions 640 and the second chamber body 120 and is located at the second opening 190. Thus, the baffle 800 is able to prevent the heat exchange efficiency of the airflow F generated by the fans 700 relative to the working fluid from being affect due to the leaking of the airflow F from the second opening 190. In other embodiments, the heat dissipation assembly may omit the baffle 800.

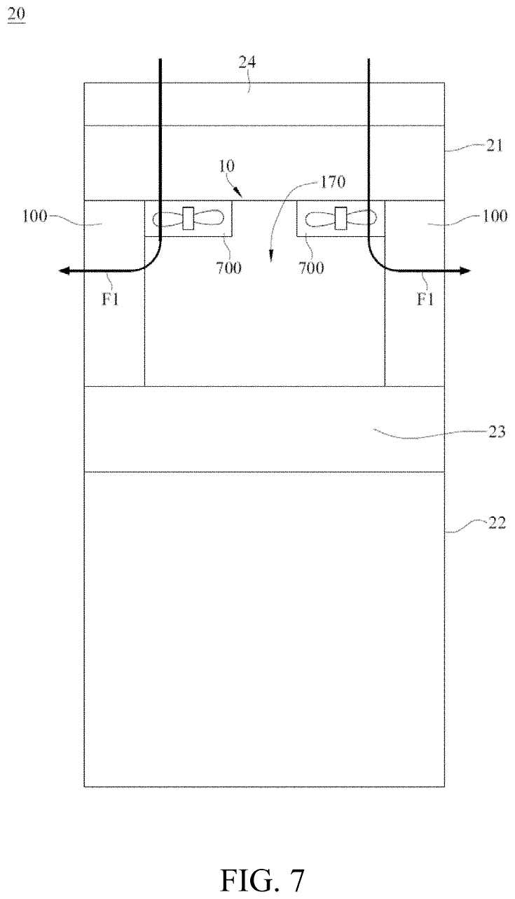

Please refer to FIG. 7, FIG. 7 is a side view of an electronic assembly according to one embodiment of the invention. In this embodiment, the electronic assembly 20 is configured for a working fluid to flow therethrough and includes a rack 21, a housing 22, an electronic device 23, and a heat dissipation assembly 10 and a filter 24 as discussed in the previous embodiment with reference to FIGS. 1-4. The housing 22 is disposed on the rack 21. The electronic device 23 is disposed in the housing 22 and may be a server. The heat dissipation assembly 10 is disposed on the rack 21 and located at a side of the housing 22. The condensers 100 of the heat dissipation assembly 10 are in fluid communication with the electronic device 23 and configured to cool heat source (not shown) in the electronic device 23. The filter 24 is disposed on a side of the heat dissipation assembly 10 located away from the housing 22 so that airflow F1 generated by the fans 700 will pass through the filter 24 before reaching the heat dissipation channel 170.

According to the heat dissipation assembly and the electronic assembly discussed above, the first chamber bodies, second chamber bodies, and pipes of the condensers together define a heat dissipation channel and heat dissipation gaps which are located between the pipes and in air communication with the heat dissipation channel, thus airflow generated by fan is allowed to flow through the heat dissipation channel and the heat dissipation gaps and therefore effectively cools working fluid passing through the pipes. As such, the condenser is able to achieve a sufficient heat dissipation while being applied to a limited internal space.

In addition, the fan is able to guide airflow from the heat dissipation gaps between the pipes to the heat dissipation channel, such that the airflow flows away from the electronic device and will not affect the maintenance works of the electronic device.

Further, the fan is able to guide airflow from the heat dissipation channel to the heat dissipation gaps between the pipes, and the filter is arranged at a side of the heat dissipation assembly located away from the housing, thus airflow from the fans passes through the filter before reaching the heat dissipation channel and therefore the filter can prevent dust from accumulating on the fans or the condenser, thereby preventing the performance of the fans and the condenser from being affected by dust.

In one embodiment of the invention, the heat dissipation assembly and electronic assembly are applicable to a server, the server may be served for computing artificial intelligence (AI) or performing edge computing and may also be served as a 5G server, cloud server, or IoT server.

It will be apparent to those skilled in the art that various modifications and variations can be made to the present invention. It is intended that the specification and examples be considered as exemplary embodiments only, with a scope of the invention being indicated by the following claims and their equivalents.

What is claimed is:

1. A heat dissipation assembly, configured for a working fluid to flow therethrough, comprising:
a plurality of condensers each comprising a first chamber body, a second chamber body, and a plurality of pipes;
wherein in each of the plurality of condensers, two opposite ends of each of the plurality of pipes are respectively in fluid communication with the first chamber body and the second chamber body, every two of the plurality of pipes located adjacent to each other define a heat dissipation gap therebetween, the working fluid is configured to flow from the first chamber body to the second chamber body via the plurality of pipes;
wherein the first chamber bodies, the second chamber bodies, and the plurality of pipes of the plurality of condensers together define a heat dissipation channel therebetween, the heat dissipation channel is in air communication with the heat dissipation gaps between the plurality of pipes; and
a fan disposed on the plurality of condensers and in air communication with the heat dissipation channel and configured to guide an airflow flowing through the heat dissipation channel and the heat dissipation gaps between the plurality of pipes of the plurality of condensers so as to cool the working fluid flowing through the plurality of pipes.

2. The heat dissipation assembly according to claim 1, further comprising a fan rack, wherein the first chamber bodies of the plurality of condensers together define a first opening in air communication with the heat dissipation channel, the fan rack is disposed at the first opening and comprises a mount hole, the mount hole is in air communication with the heat dissipation channel, and the fan is disposed at the mount hole.

3. The heat dissipation assembly according to claim 2, further comprising a baffle, wherein the second chamber bodies of the plurality of condensers together define a second opening, the first opening and the second opening are respectively in air communication with the two opposite ends of the heat dissipation channel, the fan rack comprises a first plate part, a plurality of support posts, a second plate part, and a plurality of protrusions, the first plate part is disposed at the first opening, the mount hole is located on the first plate part, two opposite ends of each of the plurality of support posts are respectively fixed to the first plate part and the second plate part, the plurality of protrusions protrude from the second plate part, the baffle is located between and clamped by the plurality of protrusions and the second chamber bodies and is located at the second opening.

4. The heat dissipation assembly according to claim 1, further comprising a plurality of first connecting pipes and a plurality of second connecting pipes, the first chamber bodies of the plurality of condensers are in fluid communication with each other via the plurality of first connecting pipes, the second chamber bodies of the plurality of condensers are in fluid communication with each other via the plurality of second connecting pipes.

5. The heat dissipation assembly according to claim 4, further comprising an inflow pipe and an outflow pipe, wherein the inflow pipe is in fluid communication with one of the plurality of first connecting pipes, and the outflow pipe is in fluid communication with one of the plurality of second connecting pipes.

6. The heat dissipation assembly according to claim 1, wherein, in each of the plurality of condensers, the plurality of pipes comprises a plurality of first pipes and a plurality of second pipes, the plurality of first pipes are parallel with one another on a first reference plane and form a first row pipe, the plurality of second pipes are parallel with one another on a second reference plane and form a second row pipe, the first reference plane is parallel with the second reference plane.

7. The heat dissipation assembly according to claim 6, wherein every two of the plurality of first pipes located adjacent to each other define a first heat dissipation gap therebetween, and every two of the plurality of second pipes located adjacent to each other define a second heat dissipation gap therebetween.

8. The heat dissipation assembly according to claim 7, wherein the first heat dissipation gaps are respectively in air communication with the second heat dissipation gaps.

9. The heat dissipation assembly according to claim 6, wherein the plurality of first pipes are aligned with the plurality of second pipes.

10. The heat dissipation assembly according to claim 6, wherein the plurality of first pipes are displaced from the plurality of second pipes.

11. The heat dissipation assembly according to claim 1, wherein each of the plurality of condensers further comprises a heat sink, the heat sink comprises a plurality of heat sink fins; in each of the plurality of condensers, the plurality of heat sink fins are respectively disposed in the heat dissipation gaps among the plurality of pipes.

12. An electronic assembly, configured for a working fluid to flow therethrough, comprising:
a rack;
a housing disposed on the rack;
an electronic device disposed in the housing;
a heat dissipation assembly comprising:
a plurality of condensers each comprising a first chamber body, a second chamber body, and a plurality of pipes;
wherein in each of the plurality of condensers, two opposite ends of each of the plurality of pipes are respectively in fluid communication with the first chamber body and the second chamber body, every two of the plurality of pipes located adjacent to each other define a heat dissipation gap therebetween, the working fluid is configured to flow from the first chamber body to the second chamber body via the plurality of pipes;
wherein the first chamber bodies, the second chamber bodies, and the plurality of pipes of the plurality of condensers together define a heat dissipation channel therebetween, the heat dissipation channel is in air communication with the heat dissipation gaps between the plurality of pipes; and
a fan disposed on the plurality of condensers and in air communication with the heat dissipation channel and configured to guide an airflow flowing through the heat dissipation channel and the heat dissipation gaps between the plurality of pipes of the plurality of condensers so as to cool the working fluid flowing through the plurality of pipes;
wherein the heat dissipation assembly is disposed on the rack and located at a side of the housing, the plurality of condensers of the heat dissipation assembly are in fluid communication with the electronic device; and
a filter disposed on a side of the heat dissipation assembly located away from the housing so that the airflow guided by the fan of the heat dissipation assembly passes through the filter before reaching the heat dissipation channel.

13. A condenser, comprising:
two chamber bodies each comprising an installation surface; and
a first row pipe and a second row pipe, wherein the first row pipe comprises a plurality of first pipes, the second row pipe comprises a plurality of second pipes, two opposite ends of each of the plurality of first pipes are respectively disposed through the installation surfaces of the two chamber bodies and are respectively in fluid communication with the two chamber bodies, two opposite ends of each of the plurality of second pipes are respectively disposed through the installation surfaces of the two chamber bodies and are respectively in fluid communication with the two chamber bodies, every two of the plurality of first pipes located adjacent to each other define a first heat dissipation gap therebetween, every two of the plurality of second pipes located adjacent to each other define a second heat dissipation gap therebetween, the first heat dissipation gaps are in air communication with at least one of the second heat dissipation gaps.

14. The condenser according to claim 13, wherein the plurality of first pipes and the plurality of second pipes each comprise a plurality of pipes, the plurality of pipes are not in direct fluid communication with each other, two opposite sides of each of the plurality of pipes are respectively in fluid communication with the two chamber bodies.
